(19) United States
(12) Patent Application Publication
(10) Pub. No.: US 2026/0126609 A1
(43) Pub. Date: May 7, 2026

(54) CABLE TROUGH FOR MANAGING FIBER-OPTIC CABLES

(71) Applicant: CommScope Technologies LLC, Claremont, NC (US)

(72) Inventors: Holly SIMONS, Minneapolis, MN (US); Mark T. BRADBURY, Temecula, CA (US); Brent CAMPBELL, Minneapolis, MN (US); Ruben ARVILLA, Ciudad Juarez (MX); Adrian Eugenio PONCE, El Paso, TX (US)

(21) Appl. No.: 19/436,585

(22) Filed: Dec. 30, 2025

Related U.S. Application Data
(63) Continuation of application No. PCT/US2024/035861, filed on Jun. 27, 2024.
(60) Provisional application No. 63/524,405, filed on Jun. 30, 2023.

(51) Int. Cl. G02B 6/44; G02B 6/48; H02G 3/06; H05K 7/14; H05K 7/18

(52) U.S. Cl. CPC G02B 6/4459; G02B 6/48; H02G 3/0608; H05K 7/1491; H05K 7/186

(57) ABSTRACT

A cable management trough member designed for organized cable routing and separation within various environments. The trough member including a base with a planar top surface, bounded by a first end, a second end, and opposing sides, forming a perimeter. Extending upward from the base are a first and a second sidewall, together with the base forming a trough-like shape. An intermediary divider, situated between the sidewalls, rises from the base to a defined top edge, contributing to the structural integrity and functionality of the trough. The divider can be characterized by a materially weakened area near its base, which enhances flexibility and adaptability in cable management applications. The trough member is constructed as a single, unitary piece through an extrusion process, ensuring robustness and uniformity. The design includes distinct planar surfaces of the divider that are substantially orthogonal to the base, facilitating efficient cable organization and ease of access.

### CROSS-REFERENCE TO RELATED APPLICATION

This application is a Continuation of International Patent Application No. PCT/US2024/035861, filed on Jun. 27, 2024, which claims the benefit of U.S. Patent Application Ser. No. 63/524,405, filed on Jun. 30, 2023, the disclosures of which are incorporated herein by reference in their entireties. To the extent appropriate, a claim of priority is made to each of the above disclosed applications.

### TECHNICAL FIELD

The present disclosure relates generally to cable management structures and methods for use with telecommunication equipment and racks, and more particularly to troughs, fittings and couplings for a cable management system.

### BACKGROUND

Cable management structures play an important role in efficiently housing and organizing the large number of telecommunications cables that are associated with equipment-mounted racks in modern telecommunications systems. In particular, these cable management structures aid in ensuring that the cables extending to and from the equipment, as well as those mounted within the racks, are effectively managed and organized.

In some cases, the cable management structures can be in the form of cable racks or raceways to provide a trough-like structure mountable to the ceiling or floor of a data center. These racks or raceways enable management and routing of cables within the data center. In many cases, these cable management structures are modular, meaning that the structures can use a range of generic components such as straight sections or lateral troughs, elbows or bends, size reducers, cable drops, and other elements, which are typically joined together by a coupler or junction component to form a complete cable management structure. By utilizing these components, a customized cable management structure can be created to cater to the specific requirements of each installation. U.S. Pat. No. 6,715,719 and U.S. Pat. No. 7,471,868 show various trough systems and components that can be assembled in a variety of configurations.

Although a variety of components may be provided for improved modularity and customization, the straight sections of the cable management structures typically come in fixed lengths. As a result, many of these straight lengths may need to be cut to match the precise dimensions of the data center room, which can be labor-intensive and time-consuming, requiring careful measurement and precise cutting to ensure a proper fit.

### SUMMARY

Some aspects of the disclosure are directed to a cable management system including a straight section or other trough member configured to be mated with other modular components, which includes an intermediary divider extending upwardly from a base positioned between sidewalls of the trough member to separate and organize cables positioned within the trough member. To inhibit interference the intermediary divider does not extend all the way to the ends of the straight section, leaving a gap between the end of the divider and the end of the straight section. In many installations, the straight sections need to be customized to fit the dimensions of the equipment or data room.

One aspect of the disclosure provides a cable management system including a trough member having a base including a planar top surface, a first end, and a second end, an opposing facing bottom surface, and a first side and a second side, the first end, the second end, and the first side and the second side forming a perimeter of the base, a first sidewall and a second sidewall extending upwardly away from planar top surface of the base, wherein the first sidewall, the second sidewall, and the base define a trough shape, and an intermediary divider positioned between the first sidewall and the second sidewall, the intermediary divider extending upwardly away from the planar top surface of the base between a base portion and a top edge portion, wherein the intermediary divider defines a materially weakened area in proximity to the base portion.

In one implementation, the base, first sidewall, second sidewall and the intermediary divider are formed as a unitary, single piece member. In one implementation, the trough member is formed by an extrusion process.

In one implementation, the intermediary divider defines a first planar divider surface and a second plane or divider surface extending between the base portion and the top edge portion, wherein the first planar divider surface and the second planar divider surface face away from one another. In one implementation, the first planar divider surface and the second planar divider surface are substantially orthogonal to the planar top surface of the base. In one implementation, a distance between the first planar surface and the second planar surface defines a wall thickness of the intermediary divider. In one implementation, a thickness of the intermediary divider in proximity to the base has a thickness of less than about 85% of the wall thickness.

In one implementation, the first and second sidewalls extend upwardly from the planar top surface of the base by a first distance, and the intermediary divider extends upwardly from the planar top surface of the base by a second distance, wherein the second distance is at least half of the first distance. In one implementation, the top edge portion of the intermediary divider defines a rounded crest.

In one implementation, the intermediary divider extends between a first intermediary divider end and a second intermediary divider end. In one implementation, the base portion of the intermediary divider defines at least one of scoring, a plurality of perforations, a channel extending at least partially along a length of the intermediary divider between a first intermediary divider end and a second intermediary divider end. In one implementation, the intermediary divider defines a single chamfered channel positioned along one edge of the base of the intermediary divider adjacent to the planar top surface, wherein the single chamfered channel serves to remove a portion of the base of the intermediary divider.

Another aspect of the present disclosure provides a method of sizing a cable management trough member, including cutting a trough member to a desired first length along a first plane, the trough member defining a base including a planar top surface extending along the longitudinal axis between a first end and a second end, a first sidewall, a second sidewall, and an intermediary divider positioned between the first sidewall and the second sidewall extending upwardly away from the planar top surface, wherein a base of the intermediary divider coupling the intermediary divider to the planar top surface defines a materially weakened area, cutting the intermediary divider to a desired second length along a second plane parallel to the first plane, wherein the second length is shorter than the first length, and bending the intermediary divider relative to the base to cause the materially weakened area to break, thereby enabling separation of a portion of the intermediary divider from the base.

In one implementation, the method further includes operably coupling the trough member a component of a modular cable management system, wherein the component comprises at least one of a bend, coupling, or cable drop portion of a modular cable management system. In one implementation, the method further includes using a tool to score a base of the intermediary divider prior to bending.

Another aspect of the present disclosure provides a cable management system including a trough member having a base defining a length extending between a first end and a second end along a longitudinal axis, a width extending between a first side and a second side along a lateral axis, and a thickness extending between a planar top surface and an opposed facing bottom surface along a vertical axis, a first sidewall coupled to the first side of the base and a second sidewall coupled to the second side of the base, the first sidewall and the second sidewall extending upwardly a first distance above the planar top surface of the base, and an intermediary divider positioned between the first sidewall and the second sidewall, the intermediary divider extending upwardly a second distance above the planar top surface of the base between a base portion and a top edge portion, wherein the intermediary divider defines a materially weakened area in proximity to the base portion to aid in separation of a portion of the intermediary divider from the base.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 is a perspective view depicting an assembled cable management system, in accordance with an embodiment of the disclosure.

FIG. 2 is a perspective view depicting a trough member in the form of a straight section including an intermediary divider, in accordance with an embodiment of the disclosure.

FIG. 3 depicts the trough member of FIG. 2, in which the trough member is cut to a desired length, in accordance with an embodiment of the disclosure.

FIG. 4 depicts the trough member of FIG. 3, in which the intermediary divider is cut to define a gap distance, in accordance with an embodiment of the disclosure.

FIG. 5 depicts the trough member of FIG. 4, in which the intermediary divider is moved relative to the base to cause separation of a materially weakened area defined by the intermediary divider, thereby easing separation of a portion of the intermediary divider from the rest of the trough member, in accordance with an embodiment of the disclosure.

FIG. 6 is a cross-sectional view of a trough member in which a materially weakened area is defined by a chamfered channel defined along one side of an intermediary divider, in accordance with an embodiment of the disclosure.

FIG. 7 is a detailed view of the intermediary divider of FIG. 6, in accordance with an embodiment of the disclosure.

FIG. 8 is a cross-sectional view of a trough member, in which a materially weakened area is defined by a pair of chamfered channels positioned on both sides of an intermediary divider, in accordance with an embodiment of the disclosure.

FIG. 9 is a detailed view of the intermediary divider of FIG. 8, in accordance with an embodiment of the disclosure.

FIG. 10 is a cross-sectional view of a trough member, in which a materially weakened area is defined by one or more grooves positioned one or more sides of an intermediary divider, in accordance with an embodiment of the disclosure.

FIG. 11 is a detailed view of the intermediary divider of FIG. 10, in accordance with an embodiment of the disclosure.

FIG. 12 is a perspective view depicting a trough member in which a line of perforations are defined along an intermediary divider, enabling portions of the intermediary divider to be more easily removed from a base, in accordance with an embodiment of the disclosure.

FIG. 13 is an exploded, perspective view depicting a pair of trough members with a first coupler positioned therebetween, in accordance with an embodiment of the disclosure.

FIG. 14 is an exploded, perspective view depicting a pair of trough members with a second coupler positioned therebetween, in accordance with an embodiment of the disclosure.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

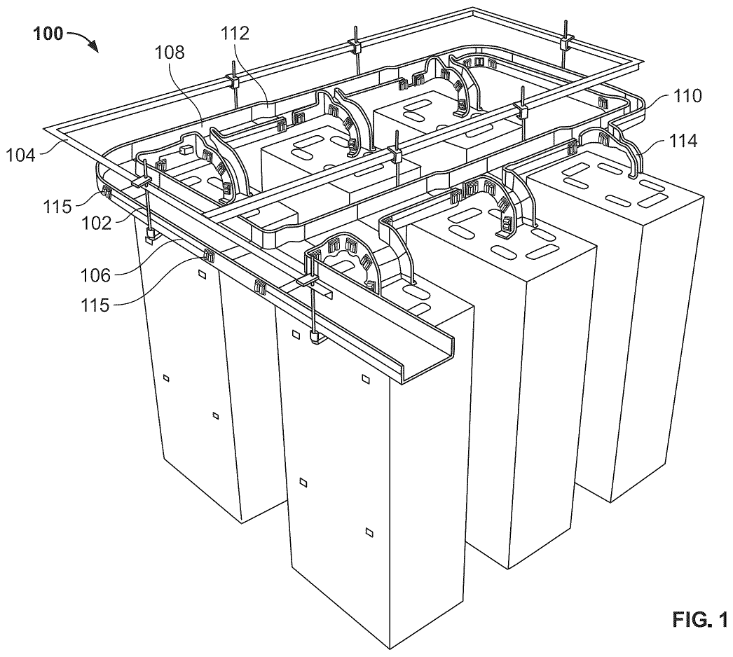

FIG. 1 illustrates a cable management rack 100, in accordance with an embodiment of the disclosure. The cable management rack 100 offers flexible installation options, enabling effectively deployment in equipment rooms or data centers for the management of cables (e.g., electrical, optical, etc.). Various methods of installing the cable management rack 100 can be employed, such as free-standing installation on the floor, wall-mounted installation, or ceiling-mounted alternatives. Ceiling-mounted options can include the use of mounting brackets, suspension systems, threaded rods or rails, as well as overhead grid systems. In the example depicted in FIG. 1, the cable management rack 100 is suspended using a plurality of mounting brackets 102, which are securely coupled to an overhead grid system 104.

In embodiments, cable management rack 100 can be a modular system comprising multiple components, which can be assembled to meet the specific dimensional requirements of the equipment room to facilitate effective cable management. As further depicted in FIG. 1, the rack components can include one or more straight sections 106 wake-up (alternatively referred to as a lateral trough), which can be interconnected with each other trough member components such as cross junctions (not depicted), T-junctions 108, elbows or L-bends 110, Z-bends (not depicted), reducers or trumpets 112, cable drops or risers 114, and end caps (not depicted), among other components. The various trough members may be operably coupled to one another via a junction or coupler 115. Examples of couplers or junctions to join components together are shown in U.S. Pat. No. 6,715,719 and U.S. Pat. No. 7,471,868, the disclosures of which are hereby incorporated by reference. In embodiments, the modular design of the cable management rack 100 enables the construction of customized cable management systems that precisely fit the layout and cable routing needs of the environment.

For example, as shown in FIG. 1, the cable management rack 100 can provide an efficient solution for routing multiple incoming cables to stacks of servers while keeping the cables elevated off the ground. The elevated cable management setup offers several advantages. In particular, the cable management rack 100 enables ease in performing tasks such as cable replacements, replacing electrical components, or swapping servers, which serves to reduce downtime, enhance system maintenance efficiency, and facilitate future upgrades or modifications. Furthermore, the cable management rack 100 aids in reducing the risk of cable entanglement, accidental damage, or obstruction.

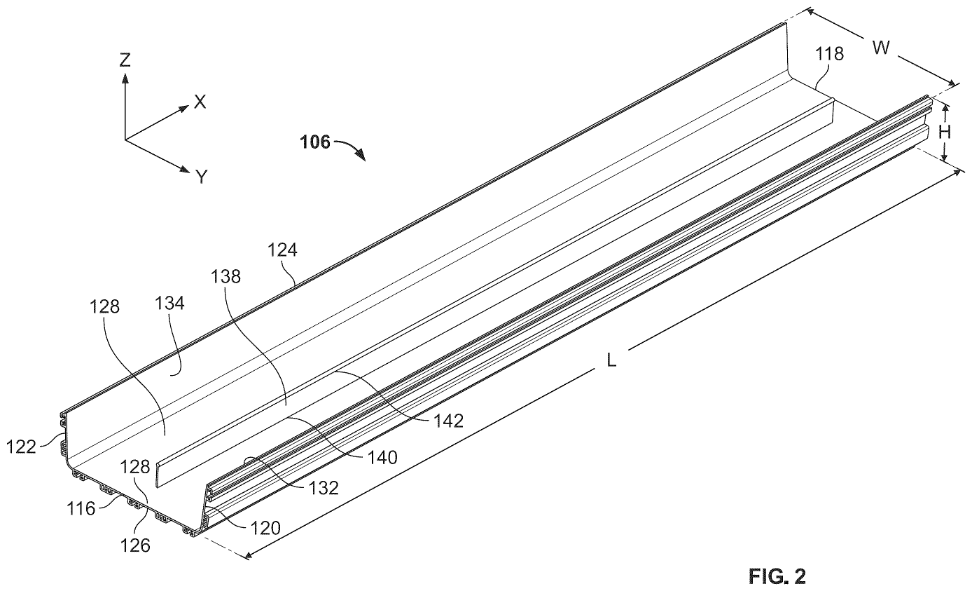

With additional reference to FIG. 2, an example trough member in the form of a straight section 106 is depicted in accordance with an embodiment of the disclosure. In embodiments, the straight section 106 can extend along a specified length (L) between a first end 116 and a second end 118 along a longitudinal axis X. For example, each straight section 106 can be of a standard length (e.g., 6 feet, 10 feet, 12 feet, etc.). Additionally, the straight section 106 can span a width (W) between a first side 120 and a second side 122 along a lateral axis Y, and a height (H) or depth between a top edge 124 and a bottom surface 126 along a vertical axis of Z, wherein the longitudinal axis X, lateral axis Y and vertical axis Z can be orthogonal to one another, collectively forming a three-dimensional coordinate system.

In embodiments, each straight section 106 can include a base 128, a pair of sidewalls including a first sidewall 132 and a second sidewall 134, and an intermediary divider 138. In embodiments, the base 128, first sidewall 132, second sidewall 134 and intermediary divider 138 can be formed as a unitary, single piece member. For example, in some embodiments, the straight section 106 can be formed by an extrusion process, in which the angular position and dimensions of the base 128, first sidewall 132, second sidewall 134, and intermediary divider 138 are defined by a die through which an extrudable material (e.g., plastic, metal, etc.) is expressed. In some embodiments, the extrudable material can an ABS/PC resin having a flammability rating of UL-94, V-0, and an oxygen index of higher than about 28% per ASTM D2864; although the use of other materials is also contemplated.

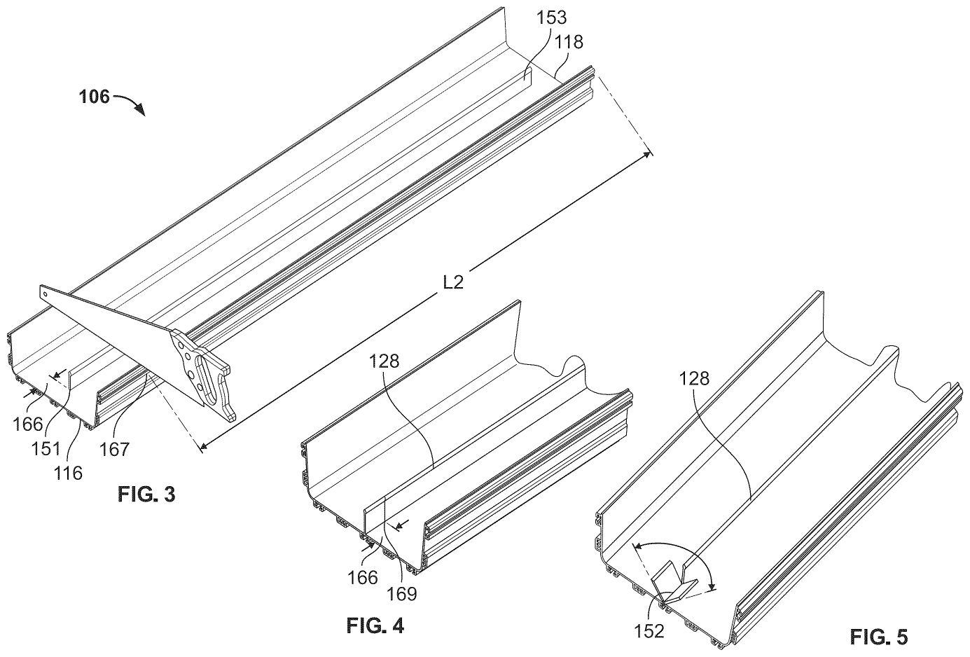

With additional reference to FIGS. 3-4, when installing the cable management rack 100, either of the first or second ends 116, 118 of the straight sections 106 can be operably coupled with other modular components (e.g., straight sections, junctions, etc.) to complete the cable management rack 100. To inhibit interference between the intermediary divider 138 and the other modular component with which the straight section 106 is coupled, typically the intermediary divider 138 does not extend all the way to the first or second end 116, 118. Rather the intermediary divider 138 terminates some distance (e.g., 1-2 inches, etc.) away from the first or second end 116, 118, thereby defining a gap distance 166 between the end 153 of the intermediary divider 138 and the first or second ends 116, 118. The gap distance 166 allows for devices like the couplers/junctions 115 to fit over the ends 116, 118, or the new end as formed when the component is cut to length, as shown.

In many installations, one or more straight sections 106 must be cut to a desired length (L2) to fit the dimensions of the equipment or data room in which the cable management rack 100 is to be installed. In doing so, the entire straight section 106 (e.g., base 128, first sidewall 132, second sidewall 134, and intermediary divider 138) is first cut 167 to a desired length (as depicted in FIG. 3), then a portion of the intermediary divider 138 is removed to redefine the gap distance 166 (as depicted in FIGS. 4-5). Removal of the portion of the intermediary divider 138 is accomplished by cutting the intermediary divider 138 along a second cut 169 (e.g., along a plane parallel to the plane of the first cut). A second cutting operation along the bottom edge of the intermediary divider 138 could be done to separate the intermediary divider 138 from the base 128. If this cut is not clean or leaves too much divider wall structure, the coupler/junction 115 may not fit over the end of the component without further manipulation or cutting operations. A saw can be used to make the first cut (e.g., to cut through the entire straight section 106 to a desired length), and a sheers or clippers can be used to make subsequent cuts to the intermediary divider 138.

Although the steps for removal of the intermediary divider 138 are relatively straightforward, removal of the portion of the intermediary divider 138 to redefine the gap distance 166 can be a time-consuming process. To address this issue, the cable management rack components of the present disclosure provide a materially weakened area 152 (as depicted in FIG. 5) between the intermediary divider 138 and the base 128 to encourage separation of the intermediary divider 138 from the base 128. Accordingly, embodiments of the present disclosure alleviate the need for users to cut along the bottom edge of the intermediary divider 138 to separate the intermediary divider 138 a from the base 128. Rather, embodiments of the present disclosure enable separation of the intermediary divider 138 by bending the intermediary divider 138 back and forth relative to the base 128, which in turn causes the materially weakened area 152 to break, thereby enabling separation of a portion of the intermediary divider 138 from the base 128, close to the base 128.

In embodiments, the base 128 can define a top surface 130, which can be opposed to the bottom surface 126 thereby forming a thin wall section generally defining a bottom or floor of the trough member, with a thickness of the base 128 generally defined between the bottom surface 126 and the top surface 130. Additionally, the base 128 can be defined by a length extending between the first end 116 and the second end 118, and a width sufficient to receive a plurality of cables defined between the first side 120 and the second side 122.

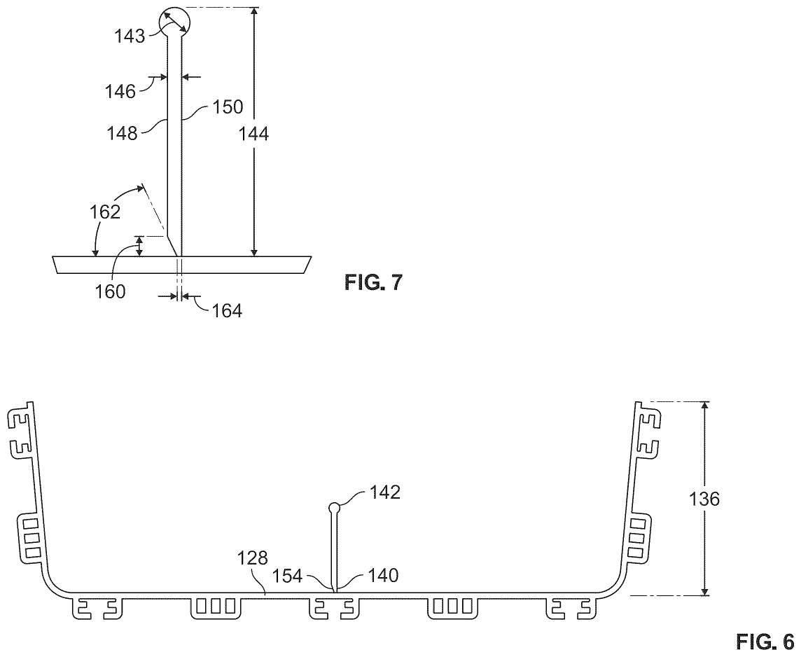

The first sidewall 132 and the second sidewall 134 can be operably coupled to the base 128, for example, in proximity to the first side 120 and the second side 122 respectively, such that the base 128, first sidewall 132 and second sidewall 134 collectively define a cable receiving trough shape. In some embodiments, the first and second sidewalls 132, 134 can extend orthogonally away from the top surface 130 of the base 128. In other embodiments, such as that depicted in FIGS. 6, 8, 10, and 12) the first and second sidewalls 132, 134 can be operably coupled to the first and second sides 120, 122 at an obtuse angle, so as to angle slightly outward from the base 128. Each of the first and second sidewalls 132, 134 can extend upwardly from the base 128 to a top edge 124, wherein the distance between the base 128 and the top edge 124 generally defines a height 136 of the first or second sidewalls 132, 134.

Further, in embodiments, the straight section 106 can define one or more intermediary dividers 138, which can be positioned generally between the first sidewall 132 and the second sidewall 134. As depicted, the straight section 106 includes a single intermediary divider 138, although the inclusion of two or more intermediary dividers is also contemplated. In embodiments, the intermediary divider 138 can generally extend upwardly away from the top surface 130 of the base 128, between a base portion 140 and a top edge portion 142, wherein a distance between the base portion 140 and the top edge portion 142 generally defines a height 144 of the intermediary divider 138. In some embodiments, the top edge portion 142 of the intermediary divider 138 can generally define a rounded crest 143 to inhibit damage to cables positioned within the straight section 106.

In some embodiments, the height 144 of the intermediary divider 138 can be less than the height 136 of the first and second sidewalls 132, 134. For example, in some embodiments, the height 144 of the intermediary divider 138 can be about half of the height 136 of the first and second sidewalls 132, 134. In some embodiments, the height 144 of the intermediary divider 138 can be greater than half of the height 136 of the first and second sidewalls 132, 134, but less than the full height 136 of the first and second sidewalls 132, 134.

As depicted, in some embodiments, the intermediary divider 138 can generally form a wall defining a first planar divider surface 148 and an opposed, second planar divider surface 150, wherein the distance between the first planar divider surface 148 and the second planar divider surface 150 represents a thickness of the intermediary divider 138. A length of the intermediary divider 138 can be defined between a first intermediary divider end 151 and a second intermediary divider end 153, wherein a distance between the first intermediary divider end 151 and the first end 116 of the base 128, or the distance between the second intermediary end 153 and the second and 118 of the base 128 define a gap distance 166. In some embodiments, the first planar divider surface 148 and the second planar divider surface 150 can be substantially orthogonal to the top surface 130.

In some embodiments, the intermediary divider 138 can define a materially weakened area 152, for example, in proximity to the base portion 140. The materially weakened portion can generally be configured to aid in separation of a portion of the intermediary divider 138 from the base 128, to aid in enabling a clean, smooth separation between the intermediary divider 138 and the base portion, so as to not leave any rough surfaces which may inadvertently cause damage to cables positioned therein.

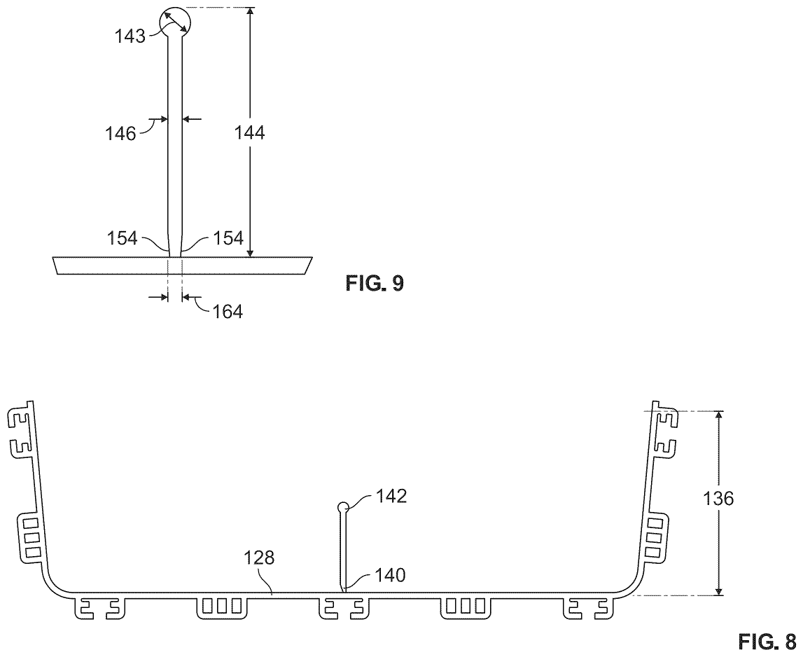

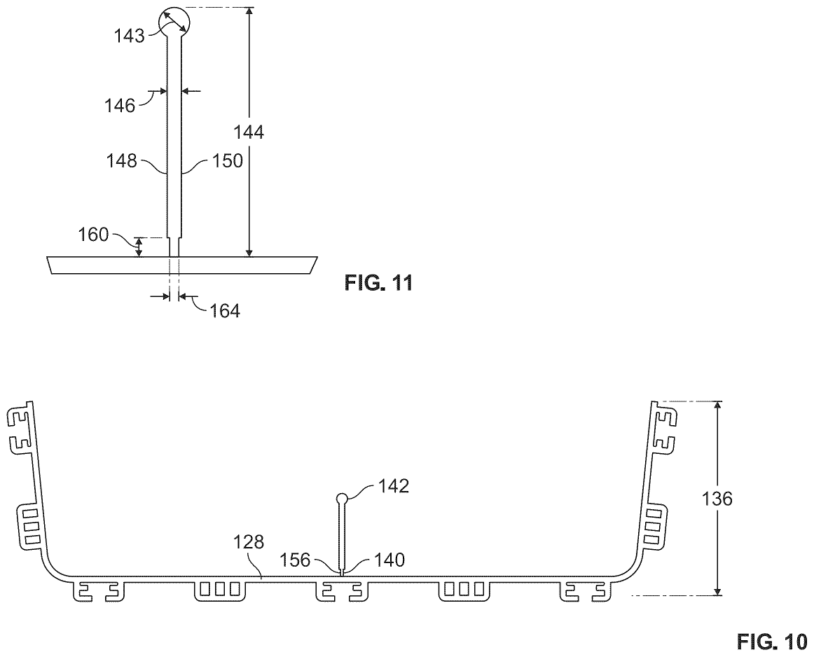

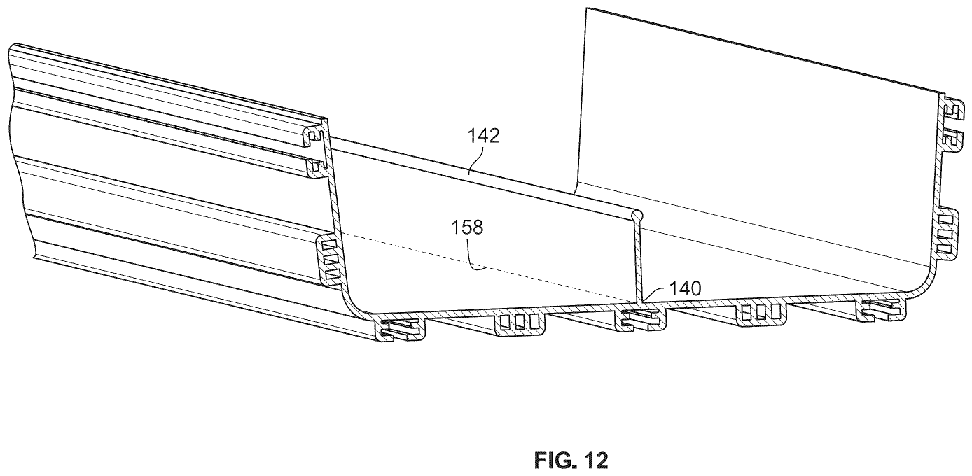

For example, with additional reference to FIGS. 7-12, the materially weakened area 152 can be in the form of a score or bevel cut 154 positioned on one side of the intermediary divider 138 (as depicted in FIGS. 6-7), a pair of bevel cuts 154, 155 positioned on both sides of the intermediary divider 138 (as depicted in FIGS. 8-9), a notch 156 defined on one or both sides of the intermediary divider 138 (as depicted in FIGS. 10-11), a line of perforations 158 defined along the base portion 140 (as depicted in FIG. 12), or the like.

With particular reference to FIGS. 6-9, in some embodiments, an edge of the bevel cut 154 can traverse through a thickness of the intermediary divider 138, for example traversing between either the first or second planar divider surface 148, 150 and a portion of the intermediary divider adjacent to the base 128. For example, as depicted, the edge of the bevel cut 154 can generally be defined by a height 160 defined along either the first or second planar divider surface 148, 150 and an angle 162 relative to the top surface 130 of the base 128, having the effect of reducing the thickness of the intermediary divider 138 from a first thickness 146 to a second thickness 164.

In some embodiments, the bevel cut 154 can be formed during the extrusion process. In other embodiments, the bevel cut 154 can be formed after completion of the extrusion process, for example by a tool (e.g., specially adapted blade, etc.) configured to execute the bevel cut 154 to define the materially weakened area 152.

With additional reference to FIGS. 10-11, in some embodiments, the notch 156 can be cut into either of the first planar divider surface 148 or the second planar divider surface 150. For example, the notch 156 can have a height 160 and a depth sufficient to reduce the thickness of the intermediary divider 138 from a first thickness 146 to a second thickness 164. In some embodiments, the second thickness 164 can have a thickness of less than about 85% of the first thickness 146; although other reductions in thickness to aid in a clean separation of the intermediary divider 138 from the base 128 are also contemplated.

With additional reference to FIG. 12, a plurality or line of perforations 158 can be defined along the base portion 140 of the intermediary divider 138. In embodiments, the perforations 158 can serve to generally weaken the connection between the intermediary divider 138 and the base 128, thereby aiding users in removing a portion of the intermediary divider 138 from the base 128.

In yet other embodiments, the materially weakened area 152 can be formed through one or more processes (e.g., heating, irradiation, etc.) aimed at breaking down the physical structure of the material in proximity to the base portion 140, thereby enabling formation of a materially weakened area 152 having a reduced strength or increased brittleness.

Embodiments of the present disclosure provide components of a cable management trough member (e.g., straight sections 106, etc.) including an intermediary divider 138 having a materially weakened area 152 configured to aid in separation of a portion of the intermediary divider 138 to ease in connectability among components of the cable management rack 100. Accordingly, in some embodiments, a method of sizing the cable management trough member can include cutting the trough member to a desired first length, wherein the first cut is made along a first plane substantially orthogonal to the top surface 130 of the base 128. Thereafter, a portion of the intermediary divider 138 can be removed by cutting the intermediary divider 138 to a desired second length along a second plane substantially parallel to the first plane to define a gap distance 166 between a first intermediary divider end 151 and a first end 116. Thereafter, the intermediary divider 138 can be bent back and forth relative to the base 128, thereby causing the materially weakened area 152 to break enabling separation of the intermediary divider 138 from the base 128.

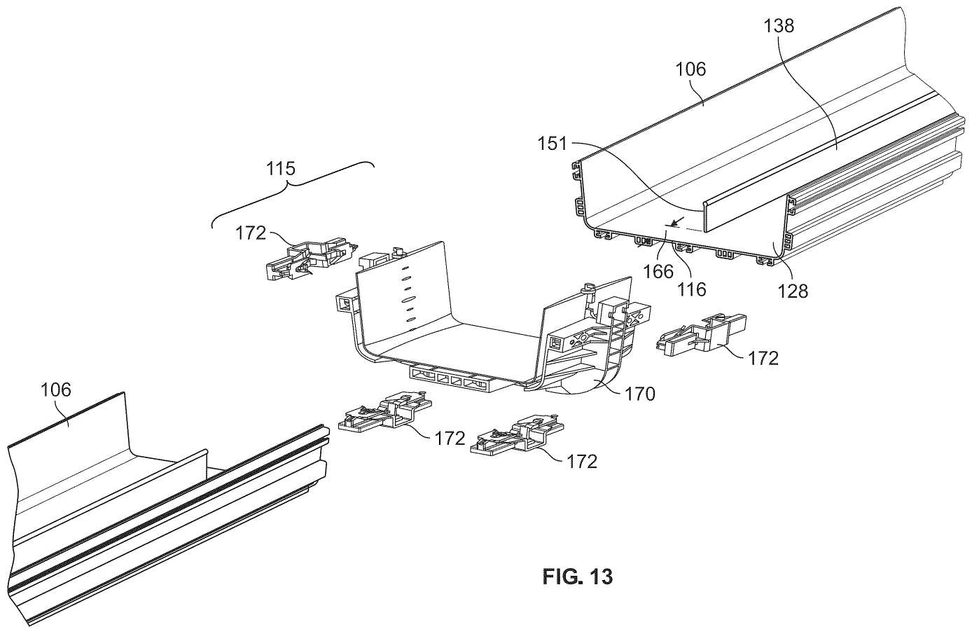

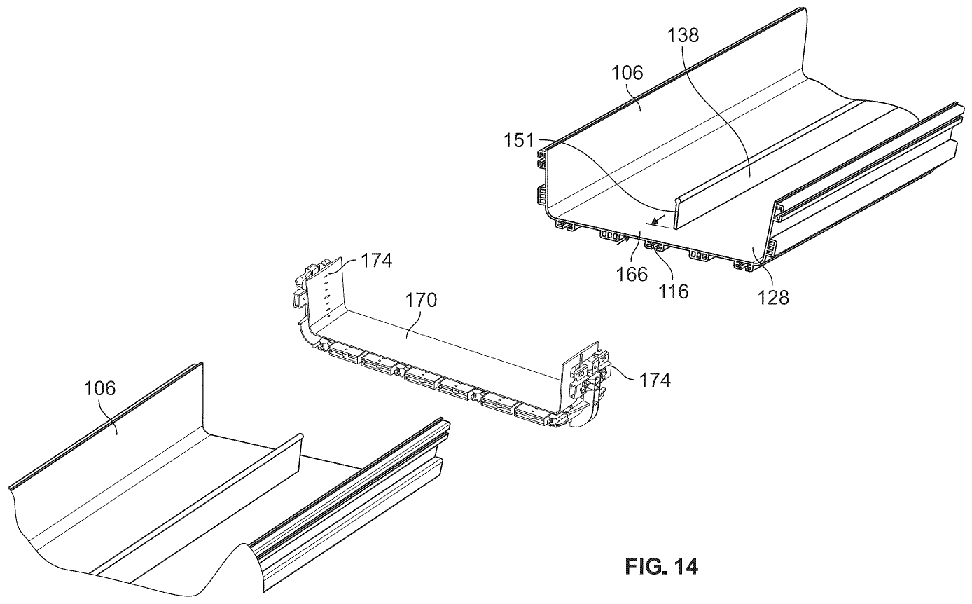

With additional reference to FIGS. 13-14, a trough member (e.g., a straight section 106) that has been appropriately sized with a portion of the intermediary divider 138 removed to define the required gap distance 166 a first intermediary divider end 151 and the first end 116 of the base 128, can be joined with other trough members via a coupler/junction 115, thereby forming a portion of a cable management structure. As depicted, various types or styles of couplers or junctions are contemplated. For example, some types of couplers 115 can include a coupler body 170 and one or more locking elements 172 (as depicted in FIG. 13). Other types of couplers 115 (e.g., such as that depicted in FIG. 14) can include a couple or body 170 with one or more snap fittings 174 formed thereon.

Accordingly, the incorporation of a materially weakened area eliminates the need for additional cutting along the bottom edge of the intermediary divider 138. This improvement simplifies the process of adjusting the length of cable management trough members (e.g., straight sections 106, and junctions including intermediary dividers), thereby saving time and labor during installation.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A cable management trough member comprising:
a base including a planar top surface, a first end, and a second end, an opposing facing bottom surface, and a first side and a second side, the first end, the second end, and the first side and the second side forming a perimeter of the base;
a first sidewall and a second sidewall extending upwardly away from the planar top surface of the base, wherein the first sidewall, the second sidewall, and the base define a trough shape; and
an intermediary divider positioned between the first sidewall and the second sidewall, the intermediary divider extending upwardly away from the planar top surface of the base between a base portion and a top edge portion, wherein the intermediary divider defines a materially weakened area in proximity to the base portion.

2. The cable management trough member of claim 1, wherein the base, the first sidewall, the second sidewall and the intermediary divider are formed as a unitary, single piece member.

3. The cable management trough member of claim 1, wherein the trough member is formed by an extrusion process.

4. The cable management trough member of claim 1, wherein the intermediary divider defines a first planar divider surface and a second planar divider surface extending between the base portion and the top edge portion, wherein the first planar divider surface and the second planar divider surface face away from one another.

5. The cable management trough member of claim 4, wherein the first planar divider surface and the second planar divider surface are substantially orthogonal to the planar top surface of the base.

6. The cable management trough member of claim 4, wherein a distance between the first planar divider surface and the second planar divider surface defines a wall thickness of the intermediary divider.

7. The cable management trough member of claim 4, wherein a thickness of the intermediary divider in proximity to the base is less than about 85% of a wall thickness.

8. The cable management trough member of claim 1, wherein the first sidewall and the second sidewall extend upwardly from the planar top surface of the base by a first distance, and the intermediary divider extends upwardly from the planar top surface of the base by a second distance, wherein the second distance is at least half of the first distance.

9. The cable management trough member of claim 1, wherein the top edge portion of the intermediary divider defines a rounded crest.

10. The cable management trough member of claim 1, wherein the intermediary divider extends between a first intermediary divider end and a second intermediary divider end.

11. The cable management trough member of claim 1, wherein the base portion of the intermediary divider defines at least one of scoring, a plurality of perforations, an channel extending at least partially along a length of the intermediary divider between a first intermediary divider end and a second intermediary divider end.

12. The cable management trough member of claim 1, wherein the intermediary divider defines a single chamfered channel positioned along one edge of the base of the intermediary divider adjacent to the planar top surface, wherein the single chamfered channel serves to remove a portion of the base of the intermediary divider.

13. A method of sizing a cable management trough member, comprising:
cutting a trough member to a first length along a first plane, the trough member defining a base including a planar top surface extending along a longitudinal axis between a first end and a second end, a first sidewall, a second sidewall, and an intermediary divider positioned between the first sidewall and the second sidewall extending upwardly away from the planar top surface, wherein a base of the intermediary divider coupling the intermediary divider to the planar top surface defines a materially weakened area;
cutting the intermediary divider to a second length along a second plane parallel to the first plane, wherein the second length is shorter than the first length; and
bending the intermediary divider relative to the base to cause the materially weakened area to break, thereby enabling separation of a portion of the intermediary divider from the base.

14. The method of claim 13, further comprising operably coupling the trough member a component of a modular cable management system, wherein the component comprises at least one of a bend, coupling, or a cable drop portion of the modular cable management system.

15. The method of claim 13, further comprising using a tool to score a base of the intermediary divider prior to bending.

16. A cable management system comprising:
a trough member including:
a base defining a length extending between a first end and a second end along a longitudinal axis, a width extending between a first side and a second side along a lateral axis, and a thickness extending between a planar top surface and an opposed facing bottom surface along a vertical axis;
a first sidewall coupled to the first side of the base and a second sidewall coupled to the second side of the base, the first sidewall and the second sidewall extending upwardly a first distance above the planar top surface of the base;
an intermediary divider positioned between the first sidewall and the second sidewall, the intermediary divider extending upwardly a second distance above the planar top surface of the base between a base portion and a top edge portion, wherein the intermediary divider defines a materially weakened area in proximity to the base portion to aid in separation of a portion of the intermediary divider from the base.

17. The cable management system of claim 16, wherein the intermediary divider defines a first planar divider surface and a second planar divider surface extending between the base portion and the top edge portion, wherein a distance between the first planar divider surface the second planar divider surface define a wall thickness of the intermediary divider, and wherein the materially weakened area in proximity to the base portion of the intermediary divider is defined by a second thickness having a smaller dimension than the wall thickness.

18. The cable management system of claim 17, wherein the materially weakened area comprises a chamfered channel extending along a longitudinal axis of the intermediary divider.

19. The cable management system of claim 17, wherein a thickness of the intermediary divider in proximity to the base is less than about 85% of the wall thickness.

20. The cable management system of claim 16, wherein the second distance is at least half of the first distance.
